(19) United States
(12) Patent Application Publication
(10) Pub. No.: US 2013/0113120 A1
(43) Pub. Date: May 9, 2013

(54) SEMICONDUCTOR DEVICE AND MANUFACTURING METHOD OF SEMICONDUCTOR DEVICE

(71) Applicants: Junji TSURUOKA, Anjo (JP); Seiji YASUI, Nagoya (JP); Osamu YAMATO, Okazaki (JP); Takayuki MAEDA, Chiryu (JP)

(72) Inventors: Junji TSURUOKA, Anjo (JP); Seiji YASUI, Nagoya (JP); Osamu YAMATO, Okazaki (JP); Takayuki MAEDA, Chiryu (JP)

(21) Appl. No.: 13/646,151

(22) Filed: Oct. 5, 2012

(30) Foreign Application Priority Data
Nov. 4, 2011 (JP) 2011-242206

(51) Int. Cl. H01L 23/52; H01L 21/58

(52) U.S. Cl. 257/784; 438/124; 257/E23.141; 257/E21.499

(57) ABSTRACT

A semiconductor device includes a metal substrate; a semiconductor element placed on the metal substrate; a flexible circuit substrate that has one end placed on the metal substrate and is electrically connected to the semiconductor element, the flexible circuit substrate extending over an edge of the metal substrate to outside the metal substrate; a resin wall portion placed, in an outer periphery of the metal substrate, at least at the edge of the metal substrate over which the flexible circuit substrate extends, the resin wall portion being provided on the flexible circuit substrate at the edge; and a resin seal portion provided inside the resin wall portion so as to cover the metal substrate.

INCORPORATION BY REFERENCE

The disclosure of Japanese Patent Application No. 2011-242206 filed on Nov. 4, 2011 including the specification, drawings and abstract is incorporated herein by reference in its entirety.

### BACKGROUND OF THE INVENTION

The present disclosure relates to a semiconductor device including a flexible circuit substrate, and a manufacturing method of the semiconductor device.

### DESCRIPTION OF THE RELATED ART

A semiconductor device including: a ceramic substrate in contact with a heat dissipater; a metal member in contact with the ceramic substrate; an electronic component mounted on the metal member; and an electrode (control terminal) placed outside the ceramic substrate, electrically connected to the electronic component by a bonding wire, and leading to the outside is conventionally known (for example, see Japanese Patent Application Publication No. 2009-088215 (JP 2009-088215 A)).

### SUMMARY OF THE INVENTION

The structure of electrically connecting the electronic component to the outside via the control terminal as in the technique described in above-mentioned JP 2009-088215 A has, however, a problem of an increase in size of the semiconductor device, because the control terminal is placed outside the substrate.

In this respect, a structure of directly attaching a flexible circuit substrate onto the substrate to achieve the electrical connection between the semiconductor element on the substrate and the outside is advantageous in that the size of the semiconductor device can be reduced. However, such a structure has a possibility that, when a resin is applied onto the substrate for sealing, the resin flows along the flexible circuit substrate and protrudes outside the substrate.

In view of this, the present disclosure has an object of providing a semiconductor device and a manufacturing method of the semiconductor device that can appropriately prevent the resin from flowing along the flexible circuit substrate and protruding outside the substrate.

According to an aspect of the present invention, a semiconductor device includes: a metal substrate; a semiconductor element placed on the metal substrate; a flexible circuit substrate that has one end placed on the metal substrate and is electrically connected to the semiconductor element, the flexible circuit substrate extending over an edge of the metal substrate to outside the metal substrate; a resin wall portion placed, in an outer periphery of the metal substrate, at least at the edge of the metal substrate over which the flexible circuit substrate extends, the resin wall portion being provided on the flexible circuit substrate at the edge; and a resin seal portion provided inside the resin wall portion so as to cover the metal substrate.

According to the aspect, it is possible to attain a semiconductor device and a manufacturing method of the semiconductor device that can appropriately prevent the resin from flowing along the flexible circuit substrate and protruding outside the substrate.

### BRIEF DESCRIPTION OF THE DRAWINGS

FIG. 1 is a perspective view showing a relevant part of a semiconductor device 1 according to an embodiment;

FIG. 2 is a main section view of the semiconductor device 1;

FIG. 3 is a view additionally showing a resin wall portion 70 in FIG. 1;

FIG. 4 is a view additionally showing the resin wall portion 70 and a resin seal portion 72 in FIG. 1; and

FIG. 5 is a view showing a comparative example that does not include the resin wall portion 70.

### DETAILED DESCRIPTION OF THE EMBODIMENTS

The following describes an embodiment with reference to drawings.

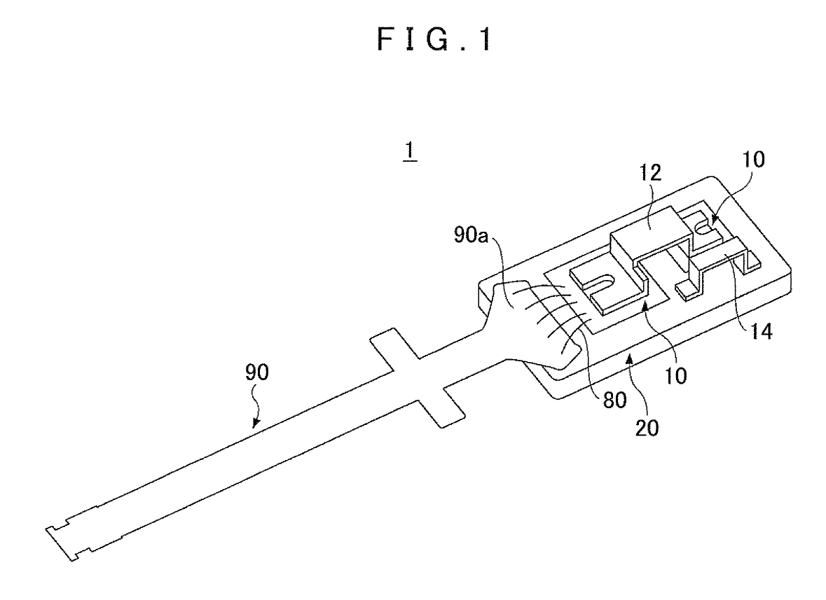

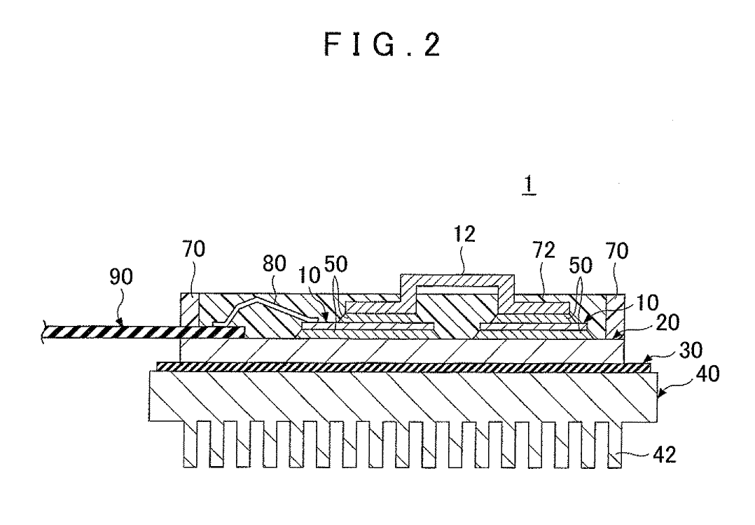

FIG. 1 is a perspective view showing a relevant part of a semiconductor device 1 according to an embodiment. FIG. 2 is a main section view of the semiconductor device 1. Note that an insulation layer 30, a heat sink 40, a resin wall portion 70, and a resin seal portion 72 of the semiconductor device 1 shown in FIG. 2 are not shown in FIG. 1 for convenience's sake.

Though up and down directions of the semiconductor device 1 vary depending on a mounting state of the semiconductor device 1, the following description is based on an assumption that a semiconductor chip 10 side of a heat spreader 20 of the semiconductor device 1 is the upper side, for convenience's sake. Moreover, the following term definitions are used. The term “outside” and “inside” are defined with respect to a center of the heat spreader 20 in a plan view in a direction perpendicular to an upper surface of the heat spreader 20. That is, “outside” means away from the center of the heat spreader 20 in the plan view, whereas “inside” means toward the center of the heat spreader 20 in the plan view. Note that the center of the heat spreader 20 does not need to be precisely determined, and may be a substantial center.

For example, the semiconductor device 1 may be included in an inverter for driving a motor, which is used in a hybrid vehicle or an electric vehicle.

The semiconductor device 1 includes the semiconductor chip 10, the heat spreader 20, the insulation layer 30, the heat sink 40, a flexible printed circuit (FPC) 90, the resin wall portion 70, and the resin seal portion 72, as shown in FIGS. 1 and 2.

The semiconductor chip 10 includes a power semiconductor element. The semiconductor chip 10 is joined onto the heat spreader 20 by solder 50. In the example shown in the drawings, two semiconductor chips 10 that are respectively an insulated gate bipolar transistor (IGBT) and a free wheeling diode (FWD) are provided on one heat spreader 20. In this case, the IGBT has an emitter electrode on its upper surface and a collector electrode on its lower surface, and the FWD has an anode electrode on its upper surface and a cathode electrode on its lower surface. Note that the type and number of power semiconductor elements included in the semiconductor chip 10 are not specifically limited. The semiconductor chip 10 may include another switching element such as a metal oxide semiconductor field-effect transistor (MOSFET), instead of the IGBT.

A first connection terminal 12 is fixed (joined) to the upper surface of the semiconductor chip 10 by the solder 50. In the example shown in the drawings, lower ends of legs of the first connection terminal 12 are respectively joined to the emitter electrode of the IGBT and the anode electrode of the FWD by the solder 50. An upper part of the first connection terminal 12 may be joined to a bus bar (not shown) by, for example, laser welding.

The heat spreader 20 is a member for absorbing and diffusing heat generated from the semiconductor chip 10. The heat spreader 20 is made of a metal having excellent thermal diffusivity, such as copper, aluminum, or the like. In this embodiment, the heat spreader 20 is made of copper, as an example. As the copper, oxygen-free copper (C1020) having highest conductivity of copper materials is preferably used.

A second connection terminal 14 is joined to the upper surface of the heat spreader 20 by solder or the like. Since the collector electrode of the IGBT as the semiconductor chip 10 (and the cathode electrode of the FWD as the semiconductor chip 10) is connected to the heat spreader 20, the second connection terminal 14 constitutes an extraction portion of the collector electrode of the IGBT. Like the first connection terminal 12, the second connection terminal 14 may be joined to a bus bar (not shown) by, for example, laser welding.

The insulation layer 30 may be made of a resin adhesive or a resin sheet. The insulation layer 30 may be made of, for example, a resin with alumina as a filler. The insulation layer 30 is provided between the heat spreader 20 and the heat sink 40, and joined to the heat spreader 20 and the heat sink 40. The insulation layer 30 ensures high thermal conductivity from the heat spreader 20 to the heat sink 40, while maintaining electrical insulation between the heat spreader 20 and the heat sink 40.

The heat sink 40 is made of a material having high thermal conductivity, for example, a metal such as aluminum. The heat sink 40 has fins 42 on its lower surface, as shown in FIG. 2. The number and arrangement pattern of fins 42 are not specifically limited. The fins 42 may be straight fins as shown in the drawing. Alternatively, the fins 42 may be realized by, for example, a staggered arrangement of pin fins. In a state where the semiconductor device 1 is implemented, the fins 42 contact a cooling medium such as cooling water or cooling air. Thus, heat generated from the semiconductor chip 10 when driving the semiconductor device 1 passes through the heat spreader 20 and the insulation layer 30 and is eventually transferred from the fins 42 of the heat sink 40 to the cooling medium, enabling the semiconductor device 1 to be cooled.

The FPC 90 has an upper surface (surface on the opposite side from a surface joined to the heat spreader 20) on which wiring (not shown) connected to a bonding wire 80 is formed (printed). The FPC 90 has one end attached onto the heat spreader 20, as shown in FIGS. 1 and 2. The FPC 90 may be joined onto the heat spreader 20 by, for example, an adhesive. In the example shown in the drawings, the FPC 90 has a wide end 90a on the heat spreader 20 side, and this end 90a is joined onto the heat spreader 20. In the example shown in the drawings, the end 90a of the FPC 90 is joined to an area, on the heat spreader 20, adjacent to the semiconductor chip 10. The FPC 90 is placed such that its part from the end 90a toward the other end extends over the edge of the heat spreader 20 to outside the heat spreader 20, as shown in FIGS. 1 and 2.

The FPC 90 is connected to the semiconductor chip 10 by the bonding wire 80 on the heat spreader 20, as shown in FIGS. 1 and 2. In the example shown in the drawings, the FPC 90 is electrically connected to the IGBT (one example of the semiconductor chip 10) by the bonding wire 80. The FPC 90 may be connected to the semiconductor chip 10 by a plurality of bonding wires 80. The plurality of bonding wires 80 may form, for example, a switching control line (gate signal line, emitter signal line), a chip temperature detection line, a sense terminal, and the like of the IGBT.

The resin wall portion 70 and the resin seal portion 72 are described below, with reference to FIGS. 2, 3, and 4.

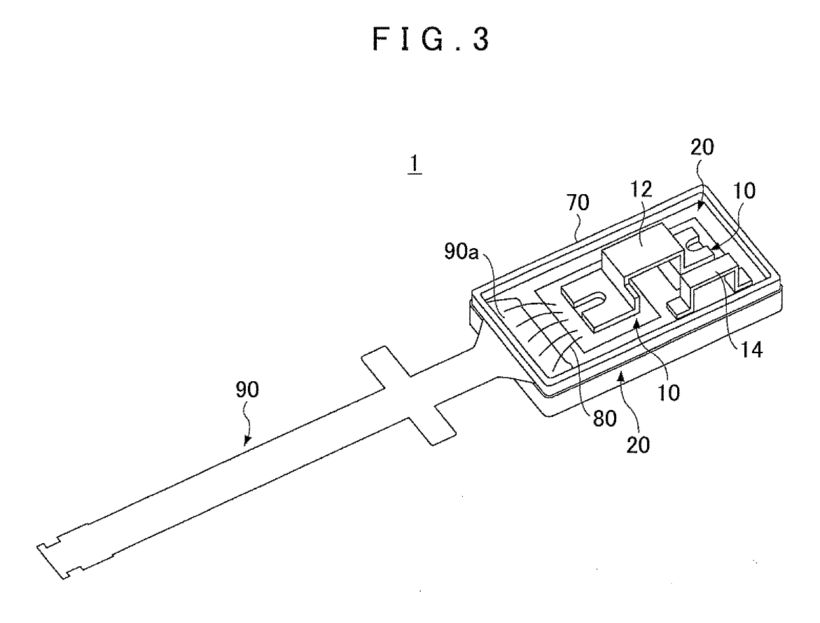

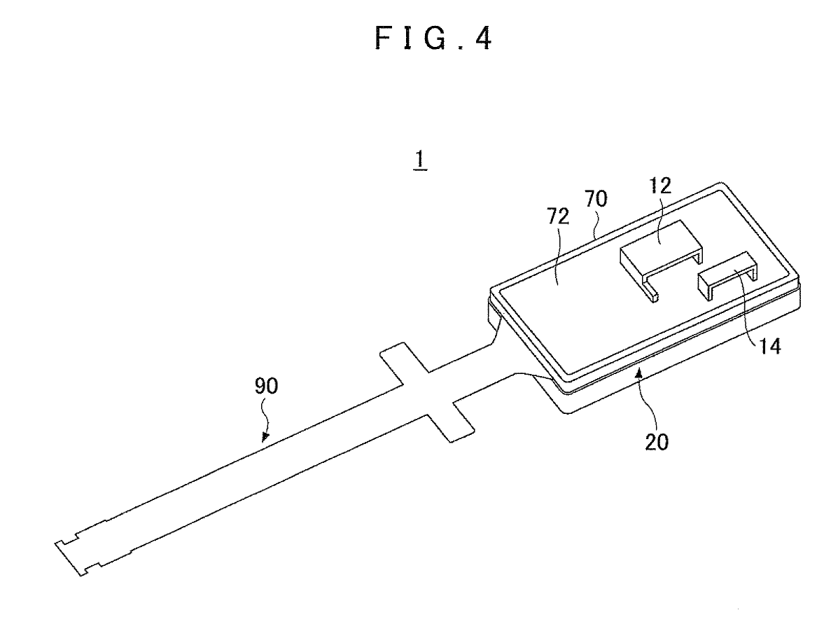

FIG. 3 is a view showing the resin wall portion 70 in FIG. 1. FIG. 4 is a view showing the resin wall portion 70 and the resin seal portion 72 in FIG. 1. That is, FIG. 2 corresponds to a main section view of the semiconductor device 1 shown in FIG. 4.

The resin wall portion 70 is provided along the entire periphery of the heat spreader 20, as shown in FIG. 3, Accordingly, at the edge where the FPC 90 extends over the heat spreader 20 (the edge of the heat spreader 20 over which the FPC 90 extends), the resin wall portion 70 is provided on the FPC 90, as shown in FIG. 2. The resin wall portion 70 may be formed by placing a resin material along the entire periphery of the heat spreader 20. The resin wall portion 70 may be made of any resin material having high viscosity and functioning as a dam material. In detail, the resin wall portion 70 is made of a highly-viscous resin material capable of maintaining its shape so as not to drop off the edge of the heat spreader 20 to the side surface of the heat spreader 20 (or so as not to protrude from the edge of the heat spreader 20 to an outside area on the FPC 90) during manufacture. Typically, the resin wall portion 70 is made of a resin material that is at least higher in viscosity than a resin material forming the resin seal portion 72. For example, the resin material of the resin wall portion 70 may contain a liquid epoxy resin and a cationic polymerization initiator as a curing agent.

The resin seal portion 72 is provided in an area surrounded by the resin wall portion 70 on the upper surface of the heat spreader 20. The resin seal portion 72 may be formed by molding a resin material into the area surrounded by the resin wall portion 70 on the upper surface of the heat spreader 20. The resin material may be any material suitable for sealing, such as a silicon gel or a thermosetting resin (e.g. epoxy resin) using an acid anhydride or phenolic curing agent.

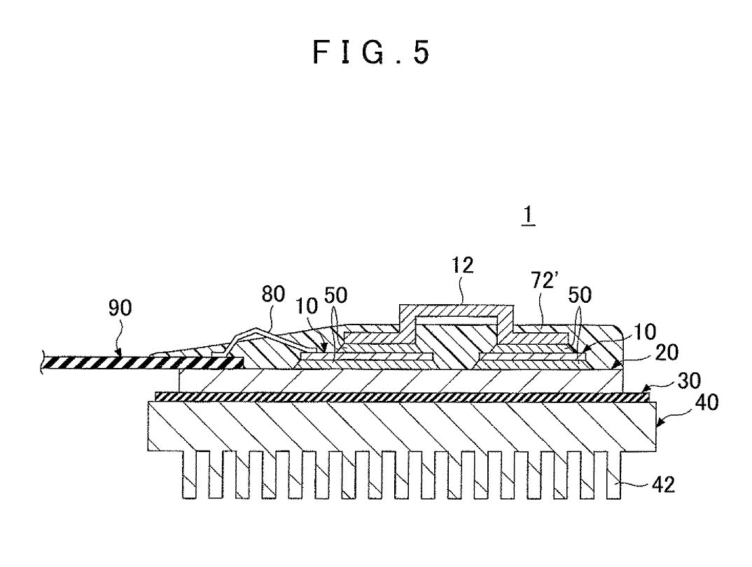

As shown in FIG. 5, in a comparative example that does not include the resin wall portion 70, there is an instance where a resin material of a resin seal portion 72′ having relatively low viscosity extends over the edge of the heat spreader 20 to outside on the FPC 90 when forming the resin seal portion 72′. This causes a possibility that an element to be sealed by the resin seal portion 72′ (especially an element located near the FPC 90, such as the bonding wire 80 in the example shown in the drawings) cannot be sealed as shown in FIG. 5.

In this embodiment, on the other hand, the resin wall portion 70 functions as a dam frame (bank) when forming the resin seal portion 72, so that the flow of the resin material to extend over the edge of the heat spreader 20 to outside on the FPC 90 is blocked. This prevents the resin seal portion 72 from protruding outside, as a result of which the element to be sealed by the resin seal portion 72 can be reliably sealed.

The resin wall portion 70 is preferably set to a height based on a highest element to be sealed by the resin seal portion 72 from among various elements placed on the heat spreader 20. In the example shown in the drawings, the highest element to be sealed by the resin seal portion 72 is the bonding wire 80. In this case, the resin wall portion 70 is set to have a height larger than that of the bonding wire 80 with respect to the upper surface of the heat spreader 20. Thus, the bonding wire 80 can be reliably sealed by the resin seal portion 72, as shown in FIG. 2.

In the example shown in FIGS. 2 and 4, the resin seal portion 72 is formed so as to cover the semiconductor chip 10 and the bonding wire 80 on the heat spreader 20. By doing so, the semiconductor chip 10 can be protected, and also the joint between the heat spreader 20 and the semiconductor chip 10 by the solder 50 and the joint between the bonding wire 80 and each of the FPC 90 and the semiconductor chip 10 can be enhanced in reliability. Besides, by covering the semiconductor chip 10 with the resin seal portion 72, it is possible to prevent a withstand voltage defect of the semiconductor chip 10 caused by spatters when laser-welding the first connection terminal 12 or the second connection terminal 14.

The following describes a manufacturing method of the semiconductor device 1 in this embodiment.

First, as shown in FIG. 1, the semiconductor chip 10 is joined onto the heat spreader 20, and the first connection terminal 12 and the second connection terminal 14 are joined respectively to the semiconductor chip 10 and the heat spreader 20. In addition, the FPC 90 is joined onto the heat spreader 20. Following this, the FPC 90 and the semiconductor chip 10 are electrically connected by the bonding wire 80 on the heat spreader 20.

Next, as shown in FIG. 3, a highly-viscous resin material (dam material) is applied along the entire periphery of the heat spreader 20, to form the resin wall portion 70. Here, since the FPC 90 is placed at a part of the periphery of the heat spreader 20, the highly-viscous resin material is applied onto the FPC 90 at this part, to form the resin wall portion 70. In the example shown in FIG. 3, the resin wall portion 70 is formed on the end 90a of the FPC 90 placed at the part of the periphery of the heat spreader 20.

Next, as shown in FIG. 4, a resin material is poured into the area surrounded by the resin wall portion 70 on the upper surface of the heat spreader 20, to form the resin seal portion 72.

In the embodiment described above, the heat spreader 20 corresponds to the “metal substrate” in the claims, and the FPC 90 corresponds to the “flexible circuit substrate” in the claims.

Though the preferred embodiment of the present invention has been described in detail above, the present invention is not limited to the embodiment described above. Various modifications and substitutions can be added to the embodiment described above, without departing from the scope of the present invention.

For example, though the resin wall portion 70 is formed along the entire periphery of the heat spreader 20 in the preferred embodiment described above, the resin wall portion 70 may be formed only at the part of the periphery of the heat spreader 20 where the FPC 90 is placed, or at a part of the periphery of the heat spreader 20 including the part where the FPC 90 is placed. In such a case, too, the flow of the resin material to extend over the edge of the heat spreader 20 to outside on the FPC 90 is blocked, so that the resin seal portion 72 can be prevented from protruding outside.

In the embodiment described above, the part of the FPC 90 located on the edge of the heat spreader 20 (the end 90a of the FPC 90 placed on the edge of the heat spreader 20 in the example shown in the drawings) may be provided with a reinforcer. The reinforcer may be made of, for example, the same material (e.g. polyimide) as the FPC 90. This reduces stress concentration in the FPC 90 caused by a force received from the edge of the heat spreader 20, which makes it possible to appropriately protect the wiring on the FPC 90.

1. A semiconductor device comprising:
a metal substrate;
a semiconductor element placed on the metal substrate;
a flexible circuit substrate that has one end placed on the metal substrate and is electrically connected to the semiconductor element, the flexible circuit substrate extending over an edge of the metal substrate to outside the metal substrate;
a resin wall portion placed, in an outer periphery of the metal substrate, at least at the edge of the metal substrate over which the flexible circuit substrate extends, the resin wall portion being provided on the flexible circuit substrate at the edge; and
a resin seal portion provided inside the resin wall portion so as to cover the metal substrate.

2. The semiconductor device according to claim 1, wherein the resin wall portion is provided along the entire outer periphery of the metal substrate.

3. The semiconductor device according to claim 2, wherein the resin seal portion is provided so as to cover an entire area of the metal substrate surrounded by the resin wall portion.

4. The semiconductor device according to claim 3, wherein
the flexible circuit substrate is connected to the semiconductor element by a bonding wire on the metal substrate,
the resin wall portion has a height larger than that of the bonding wire on the metal substrate, and
the resin seal portion is provided so as to cover the bonding wire.

5. A semiconductor device manufacturing method comprising the steps of:
placing a semiconductor element on a metal substrate;
attaching, in a state where one end of a flexible circuit substrate extends over an edge of the metal substrate to outside the metal substrate, another end of the flexible circuit substrate onto the metal substrate, and electrically connecting the flexible circuit substrate to the semiconductor element;
forming a resin wall portion along an entire outer periphery of the metal substrate onto which the flexible circuit substrate is attached; and
forming a resin seal portion so as to cover an entire area of the metal substrate surrounded by the resin wall portion.

6. The semiconductor device according to claim 1, wherein
the flexible circuit substrate is connected to the semiconductor element by a bonding wire on the metal substrate,
the resin wall portion has a height larger than that of the bonding wire on the metal substrate, and the resin seal portion is provided so as to cover the bonding wire.

7. The semiconductor device according to claim 2, wherein
the flexible circuit substrate is connected to the semiconductor element by a bonding wire on the metal substrate,
the resin wall portion has a height larger than that of the bonding wire on the metal substrate, and
the resin seal portion is provided so as to cover the bonding wire.
